(19) United States
(12) Patent Application Publication
(10) Pub. No.: US 2025/0255077 A1
(43) Pub. Date: Aug. 7, 2025

(54) DISPLAY DEVICE AND ELECTRONIC INCLUDING THE SAME

(71) Applicant: Samsung Display Co., LTD., Yongin-si (KR)

(72) Inventors: YOUNGGYU JUNG, Yongin-si (KR); YONGIL KIM, Yongin-si (KR); JAEHOON LEE, Yongin-si (KR); JUNPYO LEE, Yongin-si (KR)

(21) Appl. No.: 19/034,343

(22) Filed: Jan. 22, 2025

(30) Foreign Application Priority Data
Feb. 1, 2024 (KR) 10-2024-0015835

(51) Int. Cl. H10H 29/85; H05K 1/18

(52) U.S. Cl. CPC H10H 29/8506; H05K 1/189; H10H 29/8508; H05K 2201/10128

(57) ABSTRACT

A display device includes: a display panel including: a substrate including an ultra-thin glass and a plurality of pixels on the substrate; and a cover panel including: a first sheet under the display panel and a second sheet in direct contact with a lower surface of the first sheet and having a modulus of 30 gigapascals (Gpa) or more.

### CROSS-REFERENCE TO RELATED APPLICATION

The present application claims priority to and the benefits of Korean Patent Application No. 10-2024-0015835, filed on Feb. 1, 2024, in the Korean Intellectual Property Office (KIPO), the entire disclosure of which is incorporated herein by reference.

### BACKGROUND

### 1. Field

Aspects of some embodiments of the present disclosure relate generally to a display device.

### 2. Description of the Related Art

As information technology develops, the importance of display devices, which provide a communication medium between users and information, is being highlighted. Accordingly, the use of display devices such as a liquid crystal display device, an organic light emitting display device, a plasma display device, and the like is increasing.

The above information disclosed in this Background section is only for enhancement of understanding of the background and therefore the information discussed in this Background section does not necessarily constitute prior art.

### SUMMARY

Aspects of some embodiments of the present disclosure relate generally to a display device. For example, aspects of some embodiments relate to a display device which provides visual information.

Aspects of some embodiments include a display device including an ultra-thin glass substrate.

A display device according to some embodiments of the present disclosure includes a display panel including: a substrate including an ultra-thin glass and a plurality of pixels on the substrate, and a cover panel including: a first sheet under the display panel and a second sheet in direct contact with a lower surface of the first sheet and having a modulus of 30 Gpa (or about 30 Gpa) or more.

According to some embodiments, the second sheet may include stainless steel (SUS).

According to some embodiments, the second sheet may include aluminum (Al).

According to some embodiments, the second sheet may have a rectangular planar shape.

According to some embodiments, an end of the second sheet may include a protrusion protruding toward the display panel.

According to some embodiments, the second sheet may have an L-shape rotated counterclockwise in a cross-section.

According to some embodiments, a bending stiffness of the second sheet in a width direction may be 1.04 kgf·m (or about 1.04 kgf·m) or more.

According to some embodiments, the cover panel may further include a frame chassis under the first sheet and facing a side surface of the second sheet.

According to some embodiments, a sum of a bending stiffness of the second sheet in a width direction and a bending stiffness of the frame chassis in the width direction may be 1.04 kgf·m (or about 1.04 kgf·m) or more.

According to some embodiments, the frame chassis may have a rectangular ring shape surrounding the second sheet in a plan view.

According to some embodiments, an end of the frame chassis may include a protrusion protruding toward the display panel.

According to some embodiments, the frame chassis may include at least one of aluminum or stainless steel.

According to some embodiments, the frame chassis may include a same material as the second sheet.

According to some embodiments, the first sheet may include an embossed sheet.

A display device according to some embodiments of the present disclosure includes a display panel including: a substrate including an ultra-thin glass and a plurality of pixels in a display area on the substrate, a cover panel including: a first sheet under the display panel and including an embossed sheet and a second sheet in direct contact with a lower surface of the first sheet and having a modulus of 30 Gpa (or about 30 Gpa) or more and a bending stiffness in a width direction of 1.04 kgf·m (or about 1.04 kgf·m) or more, a first circuit board whose a first end is bonded to a first pad portion in a sub-area located around the display area of the display panel, and a part of which is bent toward a lower part of the display panel, and a second circuit board under the cover panel and including a second pad portion bonded to a second end opposite to the first end of the first circuit board.

According to some embodiments, the second sheet may include stainless steel.

According to some embodiments, the second sheet may include aluminum.

According to some embodiments, the second sheet may have a rectangular planar shape.

According to some embodiments, an end of the second sheet may include a protrusion protruding toward the display panel.

According to some embodiments, the second sheet may have an L-shape rotated counterclockwise in a cross-section.

An electronic device according to some embodiments of the present disclosure includes a display device and a processor which controls the display device, the display device includes a display panel including: a substrate including an ultra-thin glass and a plurality of pixels on the substrate and a cover panel including: a first sheet under the display panel and a second sheet in direct contact with a lower surface of the first sheet and having a modulus of 30 gigapascals (Gpa) or more.

A display device according to some embodiments of the present disclosure may include a display panel including a substrate including ultra-thin glass, and a cover panel under the display panel. The cover panel may include a first sheet and a second sheet under the first sheet, having a relatively large modulus, and having a predetermined bending stiffness. Alternatively, the cover panel of the display device may further include a frame chassis located under the display panel, and in this case, a sum of the bending stiffness of the second sheet and the bending stiffness of the frame chassis may have a predetermined value.

Accordingly, the impact resistance of the display device may be relatively improved. In addition, the curl phenomenon of the display device may be relatively minimized or reduced. In this case, the flatness of the display device may be relatively improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to some embodiments of the present disclosure.

FIG. 2 is a cross-sectional view taken along the line I-I′ of FIG. 1.

FIG. 3 is a cross-sectional view illustrating the bent shape of a first circuit board of FIG. 2.

FIG. 4 is a rear view illustrating a display panel and a cover panel of FIGS. 1 and 2.

FIG. 5 is an enlarged cross-sectional view of area A of FIG. 3.

FIG. 6 is a cross-sectional view for explaining impact resistance evaluation of the display device of FIG. 3.

FIG. 7 is a cross-sectional view illustrating further details of the display device of FIG. 3.

FIG. 8 is a cross-sectional view illustrating further details of the display device of FIG. 3.

FIG. 9 is a rear view illustrating the display panel, a second sheet, and a frame chassis of FIG. 8.

FIG. 10 is a cross-sectional view illustrating further details of the display device of FIG. 3.

FIG. 11 is a block diagram illustrating an electronic device according to some embodiments of the present disclosure.

### DETAILED DESCRIPTION

Hereinafter, a display device according to some embodiments of the present disclosure will be explained in more detail with reference to the accompanying drawings. The same reference numerals are used for the same components in the drawings, and some redundant descriptions of the same components may be omitted.

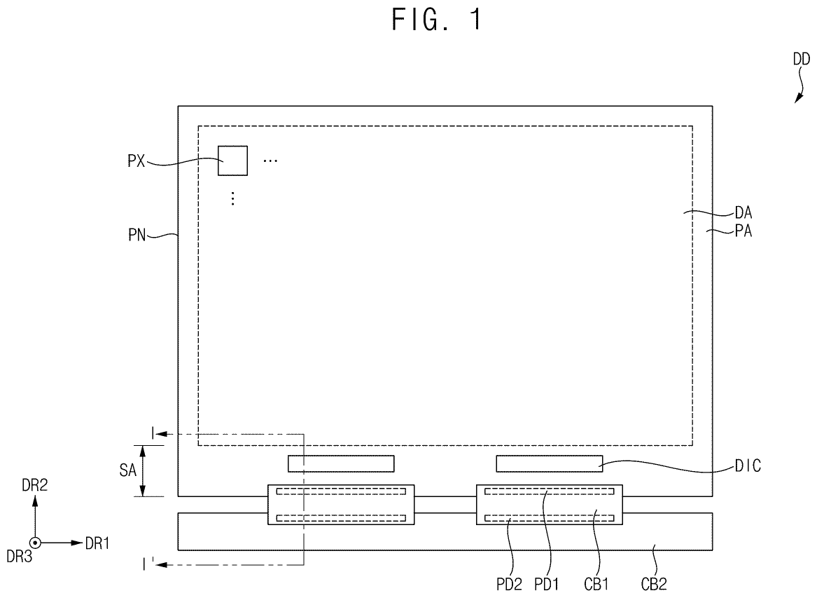

FIG. 1 is a plan view illustrating a display device according to some embodiments of the present disclosure.

Referring to FIG. 1, a display device DD according to some embodiments of the present disclosure may include a display panel PN, a driving integrated circuit DIC, a first circuit board CB1, and a second circuit board CB2.

The display panel PN may include a display area DA and a peripheral area PA. The display area DA may be defined as an area which can display images by generating light or adjusting the transmittance of light provided from an external light source. The peripheral area PA may be defined as an area which does not display images. The peripheral area PA may surround at least a part of the display area DA. For example, the peripheral area PA may entirely surround (e.g., in a periphery or outside a footprint of) the display area DA.

A plurality of pixels PX may be arranged in the display area DA. Although FIG. 1 illustrates a single pixel PX, as a person having ordinary skill in the art would appreciate, embodiments according to the present disclosure are not limited thereto, and the number of pixels PX may vary according to the design and size of the display device DD. Each of the plurality of pixels PX may emit light. As each of the plurality of pixels PX emits light, the display area DA may display images. For example, the plurality of pixels PX may be arranged in a matrix form along a first direction DR1 and a second direction DR2 crossing the first direction DR1. However, embodiments of the present disclosure are not limited thereto.

Lines connected to the plurality of pixels PX may be further located in the display area DA. For example, the lines may include data signal lines, gate signal lines, power lines, and the like.

A driver for driving a plurality of pixels PX may be located in the peripheral area PA. For example, the driver may include a data driver, a gate driver, a light emitting driver, a power supply voltage generator, and a timing controller. The plurality of pixels PX may emit light based on signals received from the drivers.

The peripheral area PA may include a sub-area SA. The sub-area SA may be arranged to be spaced apart from one side of the display area DA in a direction opposite to the second direction DR2. The sub-area SA may have a shape extending in the first direction DR1.

The driving integrated circuit DIC may be mounted in the sub area SA on the display panel PN. In this case, the driving integrated circuit DIC may be located between the first circuit board CB1 and the display area DA in a plan view. The driving integrated circuit DIC may convert a digital data signal among the driving signals into an analog data signal and provide the converted data signal to the plurality of pixels PX. For example, the driving integrated circuit DIC may be a data driver. Alternatively, the driving integrated circuit DIC may be located on the first circuit board CB1.

The driving integrated circuit DIC may be arranged in plural numbers in the sub-area SA. In this case, the driving integrated circuits DIC may be arranged to be spaced apart along the first direction DR1. For example, the number of the driving integrated circuit DIC may be two. However, the number of the driving integrated circuit DIC is not limited to this, and the number of the driving integrated circuit DIC may be one or three or more.

The display device DD may further include a first pad portion PD1 located in the sub-area SA on the display panel PN. The first pad portion PD1 may include pad electrodes for receiving signals from the outside of the display panel PN. A part of the pad electrodes of the first pad portion PD1 may be electrically connected to the driving integrated circuit DIC through a line, and the other part of the pad electrodes of the first pad portion PD1 may be electrically connected to the plurality of pixels PX through a line.

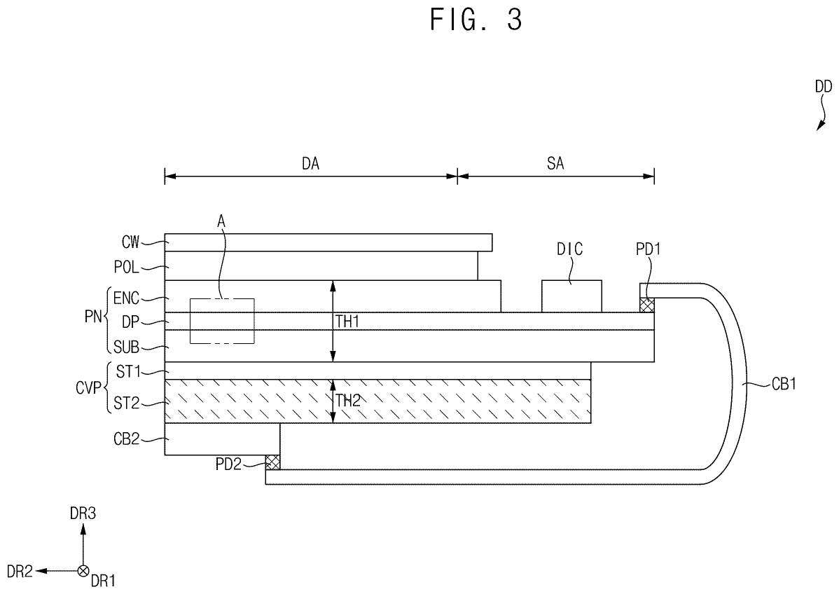

The first circuit board CB1 may be located in the sub area SA on the display panel PN. For example, the first circuit board CB1 may be arranged to overlap a part of the sub-area SA. A first end of the first circuit board CB1 may be bonded to the first pad portion PD1 located in the sub-area SA. For example, the first circuit board CB1 may include a flexible printed circuit board (FPCB). A part of the first circuit board CB1 may be bent toward a lower part of the display panel PN (see FIG. 3).

The first circuit board CB1 may be arranged in plural numbers. In this case, the first circuit boards CB1 may be spaced apart along the first direction DR1. For example, the number of the first circuit board CB1 may be two. However, the number of the first circuit board CB1 is not limited to this, and the number of the first circuit board CB1 may be one or three or more.

The second circuit board CB2 may be bonded to a second end of the first circuit board CB1 opposite to the first end. For example, a second pad portion PD2 included in the second circuit board CB2 may be bonded to the second end of the first circuit board CB1. The second circuit board CB2 may have a shape extending in the first direction DR1. For example, the second circuit board CB2 may include a printed circuit board (PCB).

In this specification, the first direction DR1 and the second direction DR2 may define a plane. For example, the second direction DR2 may be perpendicular to the first direction DR1. In addition, the third direction DR3 may be perpendicular to the plane.

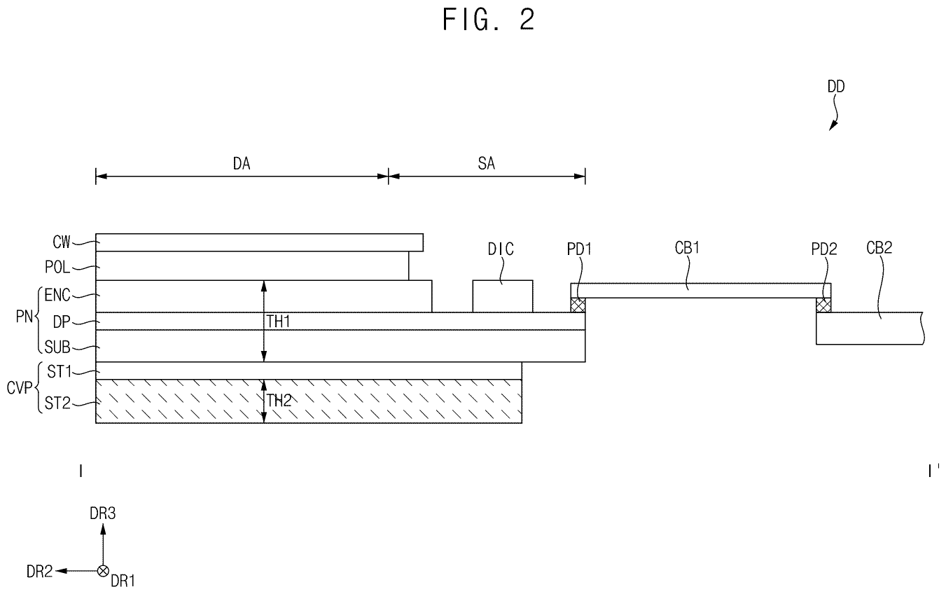

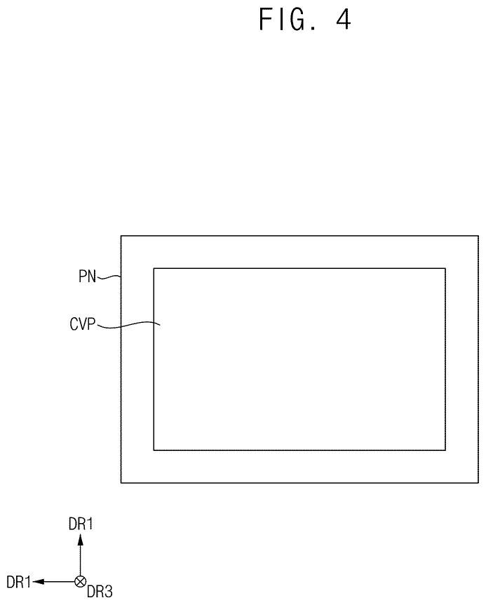

FIG. 2 is a cross-sectional view taken along the line I-I′ of FIG. 1. FIG. 3 is a cross-sectional view illustrating the bent shape of a first circuit board of FIG. 2. FIG. 4 is a rear view illustrating a display panel and a cover panel of FIGS. 1 and 2.

For example, the display device DD illustrated in FIG. 2 is in a state before the first circuit board CB1 is bent, and the display device DD illustrated in FIG. 3 is in a state in which the first circuit board CB1 is bent. The display device DD may be provided in a state in which the first circuit board CB1 is bent.

Referring to FIGS. 1, 2, 3, and 4, the display device DD according to some embodiments of the present disclosure may further include a polarizing member POL, a cover window CW, and a cover panel CVP.

The display panel PN may include a substrate SUB, a display portion DP located on the substrate SUB, and an encapsulation layer ENC located on the display portion DP.

The substrate SUB may include a transparent or opaque material. According to some embodiments, the substrate SUB may include ultra-thin glass. As the substrate SUB includes ultra-thin glass, a thickness TH1 of the display panel PN may be relatively thin. For example, when the substrate SUB includes ultra-thin glass, the thickness TH1 of the display panel PN may be 0.222 mm (or about 0.222 mm). However, embodiments of the present disclosure are not limited thereto.

The display portion DP may include a plurality of pixels (e.g., the plurality of pixels PX in FIG. 1). The display portion DP can display an image through the plurality of pixels. For example, each of the plurality of pixels may include electrical elements such as a transistor, a capacitor, a light emitting element, and the like. In addition, the display portion DP may further include insulating layers which insulate or protect the electrical elements included in each of the plurality of pixels. A detailed description of the components of the display portion DP will be described later.

The encapsulation layer ENC may prevent impurities, moisture, and the like from penetrating into the display portion DP from the outside. The encapsulation layer ENC may include at least one inorganic layer and at least one organic layer. For example, the inorganic layer may include silicon oxide, silicon nitride, silicon oxynitride, and the like. These can be used alone or in combination with each other. The organic layer may include a cured polymer such as polyacrylate. According to some embodiments, the encapsulation layer ENC may have a triple-layer structure including a first inorganic layer, a second inorganic layer, and an organic layer between the first inorganic layer and the second inorganic layer. However, embodiments of the present disclosure are not limited thereto.

The polarizing member POL may be located on the display panel PN. The polarizing member POL may reduce light reflected by the display portion DP. For example, the polarizing member POL may include a polarizing layer and a phase retardation layer. Alternatively, the polarizing member POL may be omitted, and a light blocking layer and color filters may be located on the display panel PN. Alternatively, the polarizing member POL may be omitted, and reflective layers which cause destructive interference may be located on the display panel PN.

The cover window CW may be located on the polarizing member POL. The cover window CW may transmit the image displayed by the display portion DP. In addition, the cover window CW may protect the display panel PN from the external environment. For example, the cover window CW may include a transparent material such as glass or plastic. The cover window CW may be attached to the polarizing member POL through an adhesive member.

The cover panel CVP may be located under the display panel PN. The cover panel CVP may include a first sheet ST1 and a second sheet ST2.

The first sheet ST1 may cover a rear surface of the display panel PN. The first sheet ST1 may be attached to the display panel PN through an adhesive member. For example, the first sheet ST1 may be attached to the substrate SUB through the adhesive member. The first sheet ST1 may include a front surface including subtle curves. According to some embodiments, the first sheet ST1 may include an embossed sheet. In this case, the front surface of the first sheet ST1 facing the display panel PN may be a curved surface. The curve formed in the first sheet ST1 may prevent the formation of uneven bubbles between the display panel PN and the first sheet ST1 and relatively improve the bonding force between the display panel PN and the first sheet ST1.

For example, the first sheet ST1 may have a rectangular planar shape (see FIG. 4). However, embodiments of the present disclosure are not limited to this, and the first sheet ST1 may have various planar shapes.

For example, a size of the first sheet ST1 may be smaller than a size of the display panel PN. That is, an edge of the first sheet ST1 may be closer to a center of the first sheet ST1 than an edge of the display panel PN. However, embodiments of the present disclosure are not limited thereto.

The second sheet ST2 may be located under the first sheet ST1. For example, the second sheet ST2 may be in direct contact with a lower surface of the first sheet ST1. For example, the second sheet ST2 may directly contact the entire lower surface of the first sheet ST1. The second sheet ST2 may relatively improve the impact resistance of the display device DD. Due to the second sheet ST2, the display device DD may secure sufficient stiffness. That is, the second sheet ST2 may relatively improve the flatness of the display device DD. In addition, the second sheet ST2 may shield electrostatic discharge (ESD), electromagnetic interference (EMI), and the like.

For example, the second sheet ST2 may include a metal material. According to some embodiments, the second sheet ST2 may include aluminum (Al). In this case, a thickness TH2 of the second sheet ST2 may be 0.2 mm (or about 0.2 mm). According to some embodiments, the second sheet ST2 may include stainless steel (SUS). In this case, the thickness TH2 of the second sheet ST2 may be 0.1 mm (or about 0.1 mm).

However, embodiments of the present disclosure are not limited thereto. For example, the second sheet ST2 may include glass fiber reinforced plastic (GRFP). Alternatively, the second sheet ST2 may include titanium (Ti).

The second sheet ST2 may have a relatively large modulus. According to some embodiments, the second sheet ST2 may have a modulus of 30 Gpa (or about 30 Gpa) or more. According to some embodiments, the second sheet ST2 may have a modulus of 30 Gpa (or about 30 Gpa) or more and 200 Gpa (or about 200 Gpa) or less. If the second sheet ST2 has a modulus of less than 30 Gpa (or about 30 Gpa), cracks may occur in the display panel PN when evaluating ball drop. If the second sheet ST2 has a modulus exceeding 200 Gpa (or about 200 Gpa), it may be difficult to make the display device DD lightweight.

According to some embodiments, the second sheet ST2 may have a bending stiffness of 1.04 kgf·m (or about 1.04 kgf·m) or more in a width direction (e.g., in the first direction DR1 or the second direction DR2). If the second sheet ST2 has the bending stiffness of less than 1.04 kgf·m (or about 1.04 kgf·m) in the width direction, a curl phenomenon may occur in the display device DD.

For example, the second sheet ST2 may have a rectangular planar shape (see FIG. 4). However, embodiments of the present disclosure are not limited to this, and the second sheet ST2 may have various planar shapes.

For example, a size of the second sheet ST2 may be smaller than a size of the display panel PN. That is, an edge of the second sheet ST2 may be closer to a center of the second sheet ST2 than an edge of the display panel PN. However, embodiments of the present disclosure are not limited thereto.

As described above, a part of the first circuit board CB1 may be bent toward the lower part of the display panel PN. In this case, the second circuit board CB2 may be in contact with the lower surface of the second sheet ST2 of the cover panel CVP.

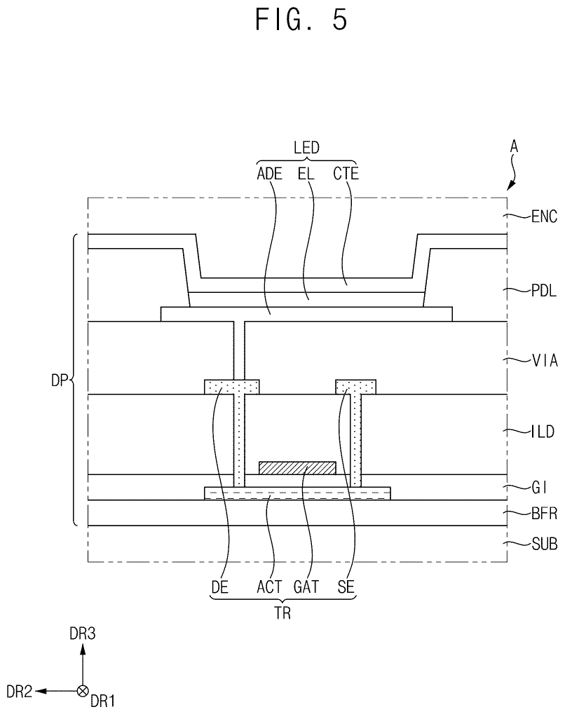

FIG. 5 is an enlarged cross-sectional view of area A of FIG. 3. For example, FIG. 5 is an enlarged cross-sectional view of a part of the display panel PN of FIG. 3.

Referring to FIG. 5, the display panel PN may include the substrate SUB, the display portion DP located on the substrate SUB, and the encapsulation layer ENC located on the display portion DP. The display portion DP may include a buffer layer BFR, a transistor TR, a gate insulating layer GI, an interlayer insulating layer ILD, a via insulating layer VIA, a pixel defining layer PDL, and light emitting element LED.

Here, the transistor TR may include an active pattern ACT, a gate electrode GAT, a source electrode SE, and a drain electrode DE, and the light emitting element LED may include an anode electrode ADE, a light emitting layer EL, and a cathode electrode CTE.

The buffer layer BFR may be located on the substrate SUB. The buffer layer BFR may prevent metal atoms or impurities from diffusing from the substrate SUB to the transistor TR. In addition, the buffer layer BFR may relatively improve the flatness of the surface of the substrate SUB when the surface of the substrate SUB is not uniform. For example, the buffer layer BFR may include an inorganic material such as silicon oxide (SiOₓ), silicon nitride (SiNₓ), silicon oxynitride (SiOxNy), and the like. These can be used alone or in combination with each other.

The active pattern ACT may be located on the buffer layer BFR. The active pattern ACT may include a metal oxide semiconductor, an inorganic semiconductor (e.g., amorphous silicon, poly silicon, and the like), or an organic semiconductor.

The active pattern ACT may include a source region, a drain region, and a channel region located between the source region and the drain region. For example, the source region and the drain region may be doped with impurities (e.g., N-type impurities or P-type impurities). The channel region may not be doped with impurities or may be doped with impurities at a lower concentration than the source region and the drain region.

The metal oxide semiconductor may include a binary compound (ABx), a ternary compound (ABxCy), a quaternary compound (ABxCyDz), and the like containing indium (In), zinc (Zn), gallium (Ga), tin (Sn), titanium (Ti), aluminum (Al), hafnium (Hf), zirconium (Zr), magnesium (Mg), and the like. For example, the metal oxide semiconductor may include zinc oxide (ZnOx), gallium oxide (GaOx), tin oxide (SnOx), indium oxide (InOx), indium gallium oxide (IGO), indium zinc oxide (IZO), indium tin oxide. (ITO), indium zinc tin oxide (IZTO), indium gallium zinc oxide (IGZO), and the like. These can be used alone or in combination with each other.

The gate insulating layer GI may be located on the buffer layer BFR. The gate insulating layer GI may sufficiently cover the active pattern ACT and may have a substantially flat upper surface without creating a step around the active pattern ACT. Alternatively, the gate insulating layer GI may cover the active pattern ACT and may be arranged along the profile of the active pattern ACT with a uniform thickness. For example, the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These can be used alone or in combination with each other.

The gate electrode GAT may be located on the gate insulating layer GI. The gate electrode GAT may overlap the channel area of the active pattern ACT. The gate electrode GAT may include metal, alloy, metal nitride, conductive metal oxide, transparent conductive material, and the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide may include indium tin oxide and indium zinc oxide. In addition, examples of the metal nitride may include aluminum nitride (AlNₓ), tungsten nitride (WNₓ), chromium nitride (CrNₓ), and the like. These can be used alone or in combination with each other.

The interlayer insulating layer ILD may be located on the gate insulating layer Gl. The interlayer insulating layer ILD may sufficiently cover the gate electrode GAT and may have a substantially flat upper surface without creating steps around the gate electrode GAT. Alternatively, the interlayer insulating layer ILD may cover the gate electrode GAT and may be arranged along the profile of the gate electrode GAT with a uniform thickness. For example, the interlayer dielectric layer ILD may include an inorganic material such as silicon oxide, silicon nitride, silicon carbide, silicon oxynitride, silicon oxycarbide, and the like. These can be used alone or in combination with each other.

The source electrode SE and the drain electrode DE may be located on the interlayer insulating layer ILD. The source electrode SE may be connected to the source region of the active pattern ACT through a contact hole penetrating a first part of the gate insulating layer GI and the interlayer insulating layer ILD, and the drain electrode DE may be connected to the drain region of the active pattern ACT through a contact hole penetrating a second part of the gate insulating layer GI and the interlayer insulating layer ILD. For example, each of the source electrode SE and the drain electrode DE may include a metal, alloy, metal nitride, conductive metal oxide, transparent conductive material, and the like. These can be used alone or in combination with each other.

Accordingly, the transistor TR including the active pattern ACT, the gate electrode GAT, the source electrode SE, and the drain electrode DE may be located in the display area DA on the substrate SUB.

The via insulating layer VIA may be located on the interlayer insulating layer ILD. The via insulating layer VIA may sufficiently cover the source electrode SE and the drain electrode DE. That is, the via insulating layer VIA may have a substantially flat upper surface.

The via insulating layer VIA may include an inorganic material or an organic material. According to some embodiments, the via insulating layer VIA may include an organic material. For example, the via insulating layer VIA may include an organic material such as phenolic resin, polyacrylates resin, polyimides resin, polyamides resin, siloxane resin, epoxy resin, and the like. These can be used alone or in combination with each other.

The anode electrode ADE may be located on the via insulating layer VIA. The anode electrode ADE may be connected to the drain electrode DE (or the source electrode SE) through a contact hole penetrating the via insulating layer VIA. For example, the anode electrode ADE may include metal, alloy, metal nitride, conductive metal oxide, transparent conductive material, and the like. These can be used alone or in combination with each other. According to some embodiments, the anode electrode ADE may have a layered structure including ITO/Ag/ITO. However, embodiments of the present disclosure are not necessarily limited thereto. The anode electrode ADE may be a reflective electrode.

The pixel defining layer PDL may be located on the via insulating layer VIA. The pixel defining layer PDL may cover the edge of the anode electrode ADE. In addition, an opening exposing at least a part of the upper surface of the anode electrode ADE may be defined in the pixel defining layer PDL. For example, the pixel defining layer PDL may include an inorganic material or an organic material. According to some embodiments, the pixel defining layer PDL may include an organic material such as epoxy resin, siloxane resin, and the like. These can be used alone or in combination with each other. According to some embodiments, the pixel defining layer PDL may include an inorganic material and/or an organic material containing a light blocking material such as black pigment, black dye, and the like.

The light emitting layer EL may be located on the anode electrode ADE. For example, the light emitting layer EL may be located in the opening of the pixel defining layer PDL. The light emitting layer EL may include an organic material which emits light of a predetermined color. For example, the light emitting layer EL may include an organic material which emits red light, green light, or blue light.

The cathode electrode CTE may be located on the pixel defining layer PDL and the light emitting layer EL. For example, the cathode electrode CTE may include metal, alloy, metal nitride, conductive metal oxide, transparent conductive material, and the like. These can be used alone or in combination with each other. The cathode electrode CTE may be a transmissive or semi-transmissive electrode.

Accordingly, the light emitting element LED including the anode electrode ADE, the light emitting layer EL, and the cathode electrode CTE may be located in the display area DA on the substrate SUB. The light emitting element LED may be electrically connected to the transistor TR. Accordingly, the light emitting element LED may receive a driving signal from the transistor TR and generate light based on the driving signal.

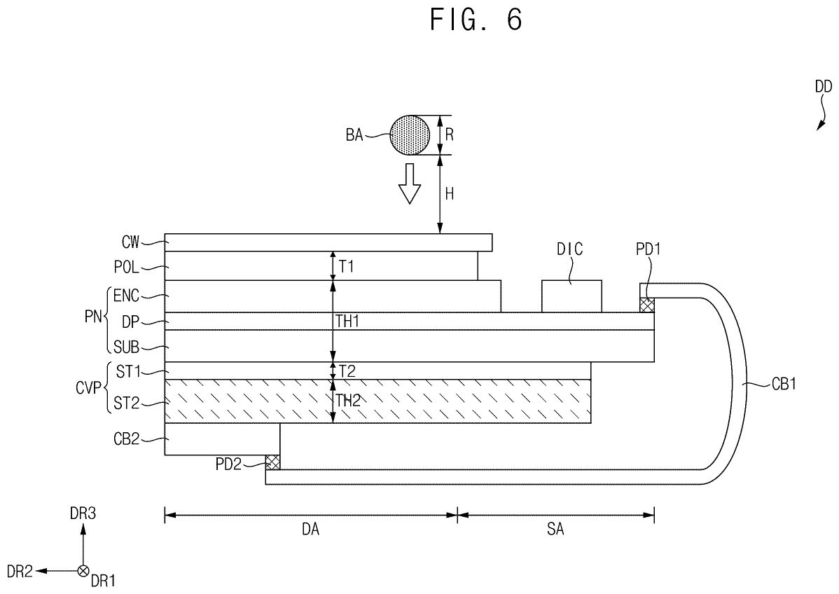

FIG. 6 is a cross-sectional view for explaining impact resistance evaluation of the display device of FIG. 3.

Referring to FIG. 6, the impact resistance of display device according to comparative example and embodiments was evaluated. The display device according to the comparative example and embodiments included the display panel PN, the polarizing member POL located on the display panel PN, and the cover panel CVP located under the display panel PN. The display panel PN used the substrate SUB including ultra-thin glass. The cover panel CVP included the first sheet ST1 including an embossed sheet and a second sheet located under the first sheet ST1. At this time, the thickness TH1 of the display panel PN was 0.222 mm (or about 0.222 mm), a thickness T1 of the polarizing member POL was 0.147 mm (or about 0.147 mm), and a thickness T2 of the first sheet ST1 was 0.03 mm (or about 0.03 mm). The display devices according to the comparative example and embodiments are substantially the same except for the second sheet.

In Comparative Example, the second sheet was formed as a molding structure using epoxy resin. In this case, referring to Table 1 below, the modulus of the second sheet was 12 Gpa (or about 12 Gpa), and the thickness of the second sheet was 0.2 mm (or about 0.2 mm).

In Embodiment 1, the second sheet ST2 was formed using glass fiber reinforced plastic (GFRP). In this case, referring to Table 1 below, the modulus of the second sheet ST2 was 30 Gpa (or about 30 Gpa), and the thickness TH2 of the second sheet ST2 was 0.2 mm (or about 0.2 mm).

In Embodiment 2, the second sheet ST2 was formed using aluminum (Al). In this case, referring to Table 1 below, the modulus of the second sheet ST2 was 70 Gpa (or about 70 Gpa), and the thickness TH2 of the second sheet ST2 was 0.2 mm (or about 0.2 mm).

In Embodiment 3, the second sheet ST2 was formed using titanium (Ti). In this case, referring to Table 1 below, the modulus of the second sheet ST2 was 120 Gpa (or about 120 Gpa), and the thickness TH2 of the second sheet ST2 was 0.2 mm (or about 0.2 mm).

In Embodiment 4, the second sheet ST2 was formed using stainless steel (SUS). In this case, referring to Table 1 below, the modulus of the second sheet ST2 was 200 Gpa (or about 200 Gpa), and the thickness TH2 of the second sheet ST2 was 0.1 mm (or about 0.1 mm).

In order to evaluate the impact resistance of the display device, a ball drop evaluation was performed on the display device. A mass of the ball BA used in the ball drop evaluation was 5.6 g (or about 5.6 g), and a diameter R of the ball BA was 11 mm (or about 11 mm). The ball BA was dropped from a height H of 19 cm (or about 19 cm) or more from the top of the display device.

TABLE 1

| | Modulus (Gpa) | Thickness (mm) | Result |
|---|---|---|---|
| Comparative | 12 | 0.2 | Broken |
| Example | | | |
| Embodiment 1 | 30 | 0.2 | Pass |
| Embodiment 2 | 70 | 0.2 | Pass |
| Embodiment 3 | 120 | 0.2 | Pass |
| Embodiment 4 | 200 | 0.1 | Pass |

As a result, referring to Table 1, it can be confirmed that cracks have occurred in the display device satisfying Comparative Example. On the other hand, it can be confirmed that no cracks occur in the display device satisfying Embodiments 1, 2, 3, and 4.

Through this, as the second sheet ST2 of the display device according to some embodiments of the present disclosure includes any one of glass fiber reinforced plastic, aluminum, titanium, and stainless steel, the second sheet ST2 may have a modulus of 30 Gpa (or about 30 Gpa) or more, and in this case, it can be confirmed that the display device has sufficient impact resistance.

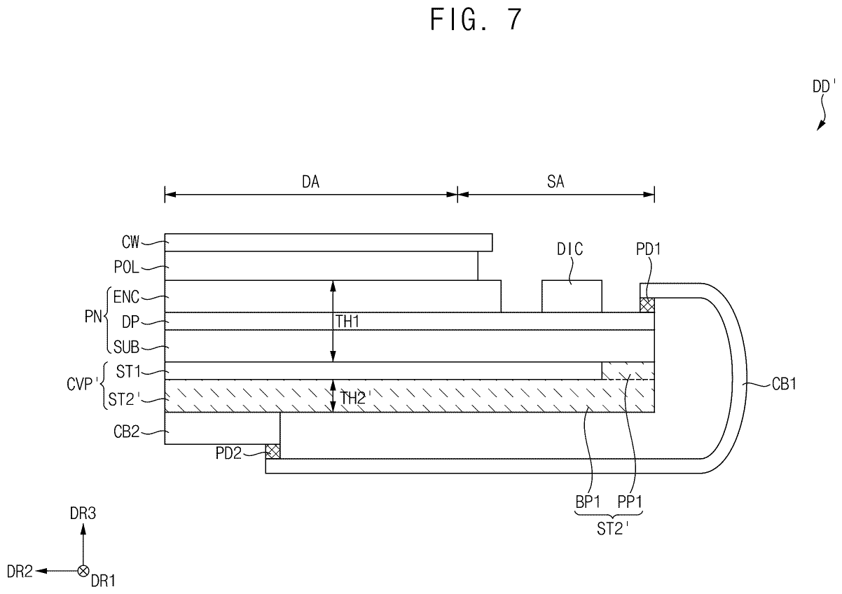

FIG. 7 is a cross-sectional view illustrating another example of the display device of FIG. 3.

Referring to FIG. 7, the display device DD′ may include the display panel PN, the polarizing member POL, the cover window CW, a cover panel CVP′, the driving integrated circuit DIC, the first circuit board CB1, the second circuit board CB2, the first pad portion PD1, and the second pad portion PD2. However, the display device DD′ described with reference to FIG. 7 may be substantially the same as or similar to the display device DD described with reference to FIG. 3 except for the cover panel CVP′. Hereinafter, descriptions that overlap with those of the display device DD described with reference to FIG. 3 will be omitted or simplified.

The cover panel CVP′ may include the first sheet ST1 and a second sheet ST2′.

The first sheet ST1 may cover the rear surface of the display panel PN. The first sheet ST1 may be attached to the display panel PN through an adhesive member. For example, the first sheet ST1 may be attached to the substrate SUB through the adhesive member. The first sheet ST1 may include the front surface including subtle curves. According to some embodiments, the first sheet ST1 may include an embossed sheet. In this case, the front surface of the first sheet ST1 facing the display panel PN may be a curved surface.

For example, the first sheet ST1 may have a rectangular planar shape (see FIG. 4). However, embodiments of the present disclosure are not limited to this, and the first sheet ST1 may have various planar shapes.

For example, the size of the first sheet ST1 may be smaller than the size of the display panel PN.

The second sheet ST2′ may be located under the first sheet ST1. For example, the second sheet ST2′ may directly contact the lower surface of the first sheet ST1. For example, the second sheet ST2′ may directly contact the entire lower surface of the first sheet ST1.

For example, the second sheet ST2′ may include a metal material. According to some embodiments, the second sheet ST2′ may include aluminum (Al) or stainless steel (SUS). However, embodiments of the present disclosure are not limited thereto. For example, the second sheet ST2′ may include glass fiber reinforced plastic (GFRP) or titanium (Ti).

According to some embodiments, an end of the second sheet ST2′ facing the first circuit board CB1 may include a protrusion PP1 protruding toward the display panel PN. That is, the second sheet ST2′ may include a body part BP1 and a protrusion PP1 protruding from the upper surface of an end of the body part BP1 facing the first circuit board CB1 toward the display panel PN. In other words, the second sheet ST2′ may have an L-shape rotated counterclockwise in a cross-section. In this case, the second sheet ST2′ may cover a part of the end of the first sheet ST1.

As the second sheet ST2′ includes the protrusion PP1, a thickness TH2′ of the second sheet ST2′ may be thinner than the thickness TH2 of the second sheet ST2 illustrated in FIGS. 2 and 3. For example, the thickness TH2′ of the body part BP1 of the second sheet ST2′ may be thinner than the thickness TH2 of the second sheet ST2 illustrated in FIGS. 2 and 3. For example, when the second sheet ST2′ includes aluminum (Al), the thickness TH2′ of the second sheet ST2′ may be 0.16 mm (or about 0.16 mm).

According to some embodiments, the second sheet ST2′ may have a modulus of 30 Gpa (or about 30 Gpa) or more. According to some embodiments, the second sheet ST2′ may have a modulus of 30 Gpa (about 30 Gpa) or more and 200 Gpa (or about 200 Gpa) or less. If the second sheet ST2′ has a modulus of less than 30 Gpa (or about 30 Gpa), cracks may occur in the display panel PN when evaluating ball drop. If the second sheet ST2′ has a modulus exceeding 200 Gpa (or about 200 Gpa), it may be difficult to make the display device DD′ lightweight.

According to some embodiments, the second sheet ST2′ may have a bending stiffness of 1.04 kgf·m (or about 1.04 kgf·m) or more in a width direction (e.g., in the first direction DR1 or the second direction DR2). If the second sheet ST2′ has the bending stiffness of less than 1.04 kgf·m (or about 1.04 kgf·m) in the width direction, a curl phenomenon may occur in the display device DD′.

As a result, since the second sheet ST2′ includes the protrusion PP1, the second sheet ST2′ may have a desired bending stiffness even though the second sheet ST2′ has a relatively thin thickness. That is, the display device DD′ of FIG. 7 may be slimmer compared to the display device DD of FIG. 3.

For example, the second sheet ST2′ may have a rectangular planar shape (see FIG. 4). However, embodiments of the present disclosure are not limited to this, and the second sheet ST2′ may have various planar shapes.

For example, the size of the second sheet ST2′ may be smaller than the size of the display panel PN. However, embodiments of the present disclosure are not limited thereto.

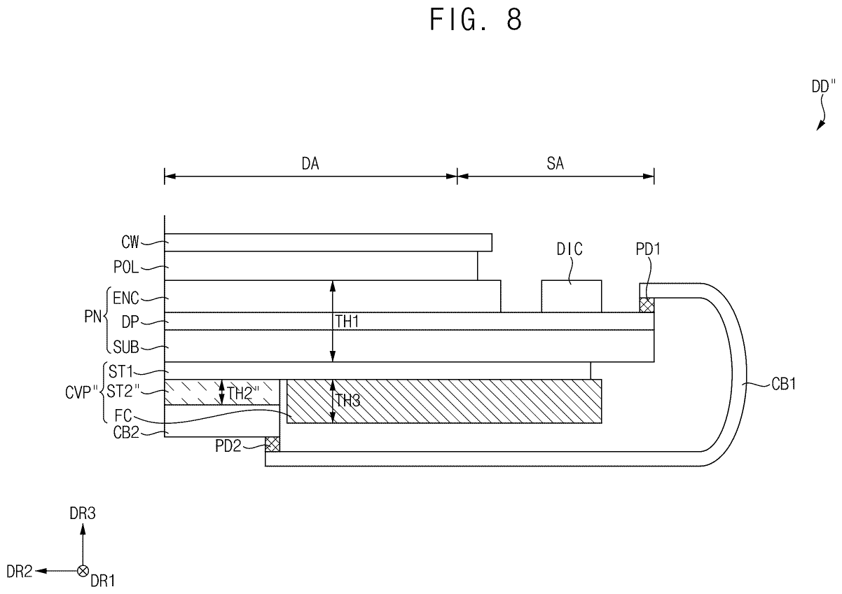

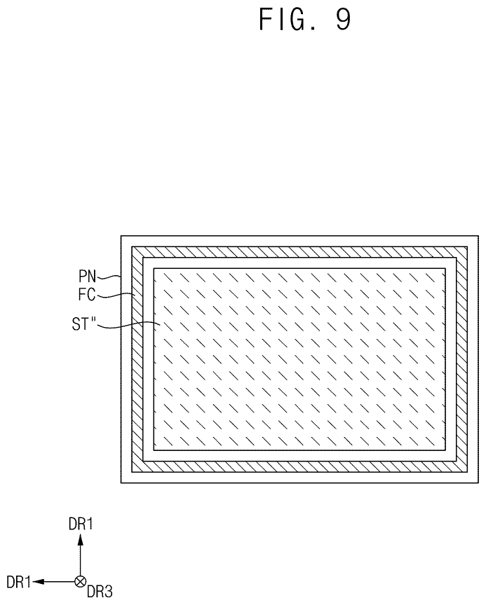

FIG. 8 is a cross-sectional view illustrating still another example of the display device of FIG. 3. FIG. 9 is a rear view illustrating the display panel, a second sheet, and a frame chassis of FIG. 8.

Referring to FIGS. 8, and 9, the display device DD″ may include the display panel PN, the polarizing member POL, the cover window CW, a cover panel CVP″, the driving integrated circuit DIC, the first circuit board CB1, the second circuit board CB2, the first pad portion PD1, and the second pad portion PD2. However, the display device DD″ described with reference to FIGS. 8 and 9 may be substantially the same as or similar to the display device DD described with reference to FIG. 3 except for the cover panel CVP″. Hereinafter, descriptions that overlap with those of the display device DD described with reference to FIG. 3 will be omitted or simplified.

The cover panel CVP″ may include the first sheet ST1 and a second sheet ST2″.

The first sheet ST1 may cover the rear surface of the display panel PN. The first sheet ST1 may be attached to the display panel PN through an adhesive member. For example, the first sheet ST1 may be attached to the substrate SUB through the adhesive member. The first sheet ST1 may include the front surface including subtle curves. According to some embodiments, the first sheet ST1 may include an embossed sheet. In this case, the front surface of the first sheet ST1 facing the display panel PN may be a curved surface.

For example, the first sheet ST1 may have a rectangular planar shape (see FIG. 4). However, embodiments of the present disclosure are not limited to this, and the first sheet ST1 may have various planar shapes.

For example, the size of the first sheet ST1 may be smaller than the size of the display panel PN.

The second sheet ST2″ may be located under the first sheet ST1. For example, the second sheet ST2″ may directly contact the lower surface of the first sheet ST1. For example, the second sheet ST2″ may directly contact a part of the lower surface of the first sheet ST1.

For example, the second sheet ST2″ may include a metal material. According to some embodiments, the second sheet ST2″ may include aluminum (Al) or stainless steel (SUS). However, embodiments of the present disclosure are not limited thereto. For example, the second sheet ST2″ may include glass fiber reinforced plastic (GFRP) or titanium (Ti).

According to some embodiments, the cover panel CVP″ may further include a frame chassis FC. The frame chassis FC may be located under the first sheet ST1 and may face the second sheet ST2″. The display device DD″ may secure sufficient stiffness thanks to the frame chassis FC.

For example, the frame chassis FC may include a metallic material. According to some embodiments, the frame chassis FC may include aluminum (Al) or stainless steel (SUS). However, embodiments of the present disclosure are not limited to this, and the frame chassis FC may include glass fiber reinforced plastic (GFRP) or titanium (Ti).

The frame chassis FC may include the same material as the second sheet ST2″. However, embodiments of the present disclosure are not limited to this, and the frame chassis FC may include a material different from the second sheet ST2″.

According to some embodiments, the frame chassis FC may have a quadrangular (e.g., rectangular) ring shape surrounding the second sheet ST2″ in the plan view. That is, the frame chassis FC may have a shape surrounding the second sheet ST2″ along an outer edge of the second sheet ST2″ in the plan view. However, the shape of the frame chassis FC is not limited to this.

The sum of a thickness TH2″ of the second sheet ST2″ and a thickness of the second circuit board CB2 may be thicker than a thickness TH3 of the frame chassis FC. For example, the thickness TH3 of the frame chassis FC may be 3 mm (or about 3 mm), and the thickness of the second circuit board CB2 may be 4 mm (or about 4 mm) or more. In this case, when the second sheet ST2″ includes aluminum (Al), the thickness TH2″ of the second sheet ST″ may be 0.038 mm (or about 0.038 mm).

According to some embodiments, the second sheet ST2″ may have a modulus of 30 Gpa (or about 30 Gpa) or more. According to some embodiments, the second sheet ST2″ may have a modulus of 30 Gpa (or about 30 Gpa) or more and 200 Gpa (or about 200 Gpa) or less. If the second sheet ST2″ has a modulus of less than 30 Gpa (or about 30 Gpa), cracks may occur in the display panel PN when evaluating ball drop. If the second sheet ST2″ has a modulus exceeding 200 Gpa (or about 200 Gpa), it may be difficult to make the display device DD″ lightweight.

According to some embodiments, a sum of the bending stiffness of the second sheet ST2″ in the width direction (e.g., the first direction DR1 or the second direction DR2) and the bending stiffness of the frame chassis FC in the width direction may be 1.04 kgf·m (or about 1.04 kgf·m) or more. If the sum of the bending stiffness of the second sheet ST2″ and the bending stiffness of the frame chassis FC is less than 1.04 kgf·m (or about 1.04 kgf·m), a curl phenomenon may occur in the display device DD″.

As a result, as the cover panel CVP″ further includes the frame chassis FC, even if the second sheet ST2″ has relatively thin thickness, the second sheet ST2″ and the frame chassis FC may be combined to achieve the desired bending stiffness. That is, the display device DD″ of FIG. 8 overlapping the second circuit board CB2 is slimmer compared to the display device DD of FIG. 3 and the display device DD′ of FIG. 7.

For example, the second sheet ST2″ may have a rectangular planar shape (see FIG. 4). However, embodiments of the present disclosure are not limited to this, and the second sheet ST2″ may have various planar shapes.

For example, the size of the second sheet ST2″ may be smaller than the size of the display panel PN. However, embodiments of the present disclosure are not limited thereto.

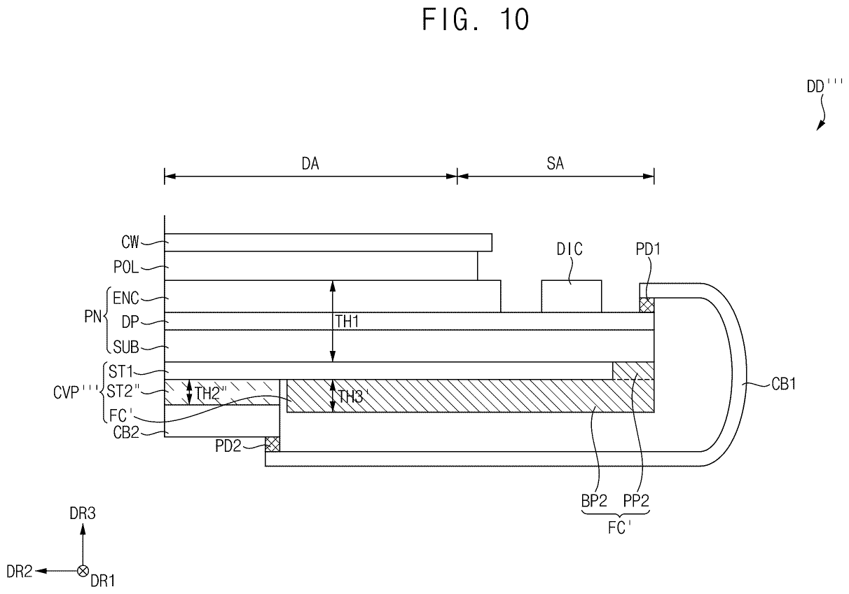

FIG. 10 is a cross-sectional view illustrating still another example of the display device of FIG. 3.

Referring to FIG. 10, the display device DD″ may include the display panel PN, the polarizing member POL, the cover window CW, a cover panel CVP″, the driving integrated circuit DIC, the first circuit board CB1, the second circuit board CB2, the first pad portion PD1, and the second pad portion PD2. However, the display device DD″ described with reference to FIG. 10 may be substantially the same as or similar to the display device DD″ described with reference to FIGS. 8 and 9 except for the cover panel CVP″. Hereinafter, descriptions that overlap with those of the display device DD″ described with reference to FIGS. 8 and 9 will be omitted or simplified.

The cover panel CVP″ may include the first sheet ST1, the second sheet ST2″, and a frame chassis FC′.

The first sheet ST1 may cover the rear surface of the display panel PN. The first sheet ST1 may be attached to the display panel PN through an adhesive member. For example, the first sheet ST1 may be attached to the substrate SUB through the adhesive member. The first sheet ST1 may include the front surface including subtle curves. According to some embodiments, the first sheet ST1 may include an embossed sheet. In this case, the front surface of the first sheet ST1 facing the display panel PN may be a curved surface.

For example, the first sheet ST1 may have a rectangular planar shape (see FIG. 4). However, embodiments of the present disclosure are not limited to this, and the first sheet ST1 may have various planar shapes.

For example, the size of the first sheet ST1 may be smaller than the size of the display panel PN.

The second sheet ST2″ may be located under the first sheet ST1. For example, the second sheet ST2″ may directly contact the lower surface of the first sheet ST1. For example, the second sheet ST2″ may directly contact a part of the lower surface of the first sheet ST1.

For example, the second sheet ST2″ may include a metal material. According to some embodiments, the second sheet ST2″ may include aluminum (Al) or stainless steel (SUS). However, embodiments of the present disclosure are not limited thereto. For example, the second sheet ST2″ may include glass fiber reinforced plastic (GFRP) or titanium (Ti).

The frame chassis FC′ may be located under the first sheet ST1 and may face the second sheet ST2″. The display device DD′″ may secure sufficient stiffness thanks to the frame chassis FC′.

For example, the frame chassis FC′ may include a metallic material. According to some embodiments, the frame chassis FC′ may include aluminum (Al) or stainless steel (SUS). However, embodiments of the present disclosure are not limited to this, and the frame chassis FC′ may include glass fiber reinforced plastic (GFRP) or titanium (Ti).

The frame chassis FC′ may include the same material as the second sheet ST2″. However, embodiments of the present disclosure are not limited to this, and the frame chassis FC′ may include a material different from the second sheet ST2″.

According to some embodiments, the frame chassis FC′ may have a quadrangular (e.g., rectangular) ring shape surrounding the second sheet ST2″ in the plan view. However, the shape of the frame chassis FC′ is not limited to this.

According to some embodiments, an end of the frame chassis FC′ facing the first circuit board CB1 may include a protrusion PP2 protruding toward the display panel PN. That is, the frame chassis FC′ may include a body part BP2 and a protrusion PP2 protruding from an upper surface of an end of the body part BP2 facing the first circuit board CB1 toward the display panel PN. In other words, the frame chassis FC′ may have an L-shape rotated counterclockwise in a cross section. In this case, the frame chassis FC′ may cover a part of the end of the first sheet ST1.

As the frame chassis FC′ includes the protrusion PP2, a thickness TH3′ of the frame chassis FC′ may be thinner than the thickness TH3 of the frame chassis FC illustrated in FIG. 8. For example, the thickness TH3′ of the body part BP2 of the frame chassis FC′ may be thinner than the thickness TH3′ of the frame chassis FC illustrated in FIG. 8.

A sum of the thickness TH2″ of the second sheet ST2″ and the thickness of the second circuit board CB2 may be thicker than the thickness TH3′ of the frame chassis FC′. For example, the thickness TH3′ of the frame chassis FC′ may be less than 3 mm (or about 3 mm), and the thickness of the second circuit board CB2 may be 4 mm (or about 4 mm) or more. In this case, when the second sheet ST2″ includes aluminum (Al), the thickness TH2″ of the second sheet ST″ may be 0.038 mm (or about 0.038 mm).

According to some embodiments, the second sheet ST2″ may have a modulus of 30 Gpa (or about 30 Gpa) or more. According to some embodiments, the second sheet ST2″ may have a modulus of 30 Gpa (or about 30 Gpa) or more and 200 Gpa (or about 200 Gpa) or less. If the second sheet ST2″ has a modulus of less than 30 Gpa (or about 30 Gpa), cracks may occur in the display panel PN when evaluating ball drop. If the second sheet ST2″ has a modulus exceeding 200 Gpa (or about 200 Gpa), it may be difficult to make the display device DD″ lightweight.

According to some embodiments, a sum of the bending stiffness of the second sheet ST2″ in the width direction (e.g., the first direction DR1 or the second direction DR2) and the bending stiffness of the frame chassis FC′ in the width direction may be 1.04 kgf·m (or about 1.04 kgf·m) or more. If the sum of the bending stiffness of the second sheet ST2″ and the bending stiffness of the frame chassis FC′ is less than 1.04 kgf·m (or about 1.04 kgf·m), a curl phenomenon may occur in the display device DD″.

As a result, as the cover panel CVP′″ further includes the frame chassis FC′, even if each of the second sheet ST2″ and the frame chassis FC′ has relatively thin thickness, the second sheet ST2″ and the frame chassis FC′ may be combined to achieve the desired bending stiffness. That is, the display device DD″″ of FIG. 10 is slimmer compared to the display device DD′ of FIG. 8.

For example, the second sheet ST2″ may have a rectangular planar shape (see FIG. 4). However, embodiments of the present disclosure are not limited to this, and the second sheet ST2″ may have various planar shapes.

For example, the size of the second sheet ST2″ may be smaller than the size of the display panel PN. However, embodiments of the present disclosure are not limited thereto.

Referring again to FIGS. 1, 2, 3, 4, 5, 6, 7, 8, 9, and 10, the display device DD and DD′ according to some embodiments of the present disclosure may include the display panel PN including the substrate SUB including ultra-thin glass, and the cover panel CVP and CVP′ located under the display panel PN. The cover panel CVP and CVP′ may include the first sheet ST1 and the second sheet ST2 and ST2′ located under the first sheet ST1, having a relatively large modulus (e.g., a modulus of 30 Gpa (or about 30 Gpa) or more), and having a predetermined bending stiffness (e.g., a bending stiffness of 1.04 kgf·m (or about 1.04 kgf·m) or more). Alternatively, the cover panel CVP″ and CVP″ of the display device DD″ and DD″ may further include the frame chassis FC and FC′ located under the display panel PN, and in this case, a sum of the bending stiffness of the second sheet ST2″ and the bending stiffness of the frame chassis FC and FC′ may have a predetermined value (e.g., a bending stiffness of 1.04 kgf·m (or about 1.04 kgf·m) or more).

Accordingly, the impact resistance of the display device DD, DD′, DD″, and DD″ may be relatively improved. In addition, the curl phenomenon of the display device DD, DD′, DD″, and DD″ may be minimized or reduced. In this case, the flatness of the display device DD, DD′, DD″, and DD″ may be relatively improved.

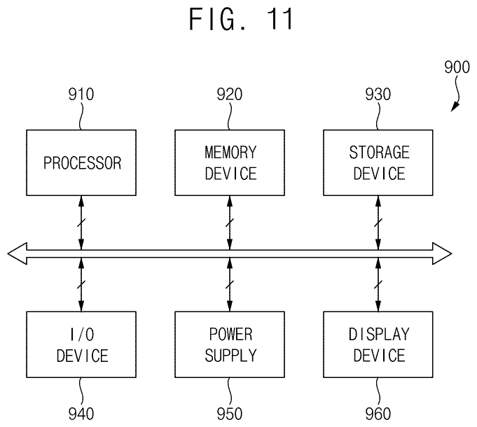

FIG. 11 is a block diagram illustrating an electronic device according to some embodiments of the present disclosure.

Referring to FIG. 11, in an embodiment, an electronic device 900 may include a processor 910, a memory device 920, a storage device 930, an input/output device 940, a power supply 950, and a display device 960. In this case, the display device 960 may correspond to the display device DD, DD′, DD″ or DD″ described with reference to FIGS. 1 to 10. The electronic device 900 may further include several ports capable of communicating with a video card, a sound card, a memory card, a USB device, and the like.

In an embodiment, the electronic device 900 may be implemented as a television. In another embodiment, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. The processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and characteristics of embodiments according to the present disclosure. Accordingly, all such modifications are intended to be included within the scope of embodiments according to the present disclosure as defined in the appended claims, and their equivalents. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A display device comprising:
a display panel including: a substrate including an ultra-thin glass and a plurality of pixels on the substrate; and
a cover panel including: a first sheet under the display panel and a second sheet in direct contact with a lower surface of the first sheet and having a modulus of 30 gigapascals (Gpa) or more.

2. The display device of claim 1, wherein the second sheet includes stainless steel (SUS).

3. The display device of claim 1, wherein the second sheet includes aluminum (Al).

4. The display device of claim 1, wherein the second sheet has a rectangular planar shape.

5. The display device of claim 1, wherein an end of the second sheet includes a protrusion protruding toward the display panel.

6. The display device of claim 5, wherein the second sheet has an L-shape rotated counterclockwise in a cross-section.

7. The display device of claim 1, wherein a bending stiffness of the second sheet in a width direction is 1.04 kgf·m or more.

8. The display device of claim 1, wherein the cover panel further includes:
a frame chassis under the first sheet and facing a side surface of the second sheet.

9. The display device of claim 8, wherein a sum of a bending stiffness of the second sheet in a width direction and a bending stiffness of the frame chassis in the width direction is 1.04 kgf·m or more.

10. The display device of claim 8, wherein the frame chassis has a rectangular ring shape surrounding the second sheet in a plan view.

11. The display device of claim 8, wherein an end of the frame chassis includes a protrusion protruding toward the display panel.

12. The display device of claim 8, wherein the frame chassis includes at least one of aluminum or stainless steel.

13. The display device of claim 8, wherein the frame chassis includes a same material as the second sheet.

14. The display device of claim 1, wherein the first sheet includes an embossed sheet.

15. A display device comprising:
a display panel including: a substrate including an ultra-thin glass and a plurality of pixels in a display area on the substrate;
a cover panel including: a first sheet under the display panel and including an embossed sheet and a second sheet in direct contact with a lower surface of the first sheet and having a modulus of 30 gigapascals (Gpa) or more and a bending stiffness in a width direction of 1.04 kgf·m or more;
a first circuit board whose a first end is bonded to a first pad portion in a sub-area located around the display area of the display panel, and a part of which is bent toward a lower part of the display panel; and
a second circuit board under the cover panel and including a second pad portion bonded to a second end opposite to the first end of the first circuit board.

16. The display device of claim 15, wherein the second sheet includes stainless steel.

17. The display device of claim 15, wherein the second sheet includes aluminum.

18. The display device of claim 15, wherein the second sheet has a rectangular planar shape.

19. The display device of claim 15, wherein an end of the second sheet includes a protrusion protruding toward the display panel, and
wherein the second sheet has an L-shape rotated counterclockwise in a cross-section.

20. An electronic device comprising:
a display device; and
a processor which controls the display device,
wherein the display device includes:
a display panel including: a substrate including an ultra-thin glass and a plurality of pixels on the substrate; and
a cover panel including: a first sheet under the display panel and a second sheet in direct contact with a lower surface of the first sheet and having a modulus of 30 gigapascals (Gpa) or more.
